(19) United States
(12) Patent Application Publication
(10) Pub. No.: US 2006/0259850 A1
(43) Pub. Date: Nov. 16, 2006

(54) ERROR CORRECTING APPARATUS

(75) Inventor: Shin-ichiro Tomisawa, Gifu (JP)

Correspondence Address: Gregory A. Walters, FISH & RICHARDSON P.C., P.O.BOX 1022, MINNEAPOLIS, MN, 55440-1022, US

(73) Assignee: SANYO ELECTRIC CO., LTD, Osaka (JP)

(21) Appl. No.: 11/380,398

(22) Filed: Apr. 26, 2006

(30) Foreign Application Priority Data
Apr. 26, 2005 (JP) 2005-128053

(51) Int. Cl. H03M 13/03

(52) U.S. Cl. 714/793

(57) ABSTRACT

An error correcting apparatus performing error correction of a block code constituted by first and second error correcting codes includes a syndrome calculating unit that performs syndrome calculations based on the first error correcting code in each row in concurrence with storing of the block code into a buffer memory to generate a determination result of presence or absence of one or more errors in each row, a buffering unit that buffers the determination result, and a correction processing unit that performs a correction process based on the second error correcting code of each column of the block code read from the buffer memory and the buffered determination result. The buffering unit may be replaced with a buffer transferring unit that transfers the determination result generated by the syndrome calculating unit to the buffer memory and a buffering unit that reads from the buffer memory and buffers the determination result.

### CROSS-REFERENCE TO RELATED APPLICATIONS

The present application claims priority from Japanese Patent Application No. 2005-128053 filed on Apr. 26, 2005, which is herein incorporated by reference.

### BACKGROUND OF THE INVENTION

1. Field of the Invention

The present invention relates to an error correcting apparatus.

2. Description of the Related Art

Error correction technology is technology necessary for improving credibility of systems such as a communication system, a broadcast system, a recording system, etc. and is basic technology for achieving a higher density of audio recording and video recording in the recording system. With regard to error correction codes, which constitute the core of the error correcting technology, many studies have been conducted and various codes are proposed.

The error correction code system is classified into major categories of block codes and convolution code; the block codes are classified into linear codes and nonlinear codes; and the linear codes are classified into cyclic codes and noncyclic codes. These codes are classified into product codes and concatenated codes, which further improve error correcting capability by combining at least two types of the codes or two same types of the codes. For example, the Read Solomon product code is used in optical disk recording such as DVD standards, digital VTRs, etc., is the Read Solomon code (one of the cyclic codes described above) using codewords constituted by particular elements called Galois fields, and is effective mainly for burst errors.

Description will be made of an encoding process in conformity with the DVD standard based on the Read Solomon product code by way of example of the error correction code with reference to FIGS. 16, 17, and 18.

Recording data to be recorded onto an optical disk are divided into 2048-byte data as shown in FIG. 16. This divided data are referred to as “main data” and a 12-byte “header” is added to the beginning thereof. This header is constituted by a four-bit ID (Identification Code), a two-byte error detection code IED (Id Error Detection Code) for the ID, and a six-byte reservation data CPM (Copyright Management Code) such as copy protect information. A four-byte EDC (Error Detection Code) is added to the end of the main data. The EDC is an error correction code for the main data with the header added.

The total of 2064-byte data constituted by adding the header and the EDC to the main data are sectioned into 172 bytes (columns)×12 rows of “data sectors”, which is delimited by every 172 bytes. For 2048-byte main data of the data sectors, a scramble process is performed by PN (Pseudo random Noise) series addition based on information of a scrambling key included in the header.

A matrix of 172 bytes×192 rows (hereinafter, “data sector group”) is formed by aggregating 16 data sectors. Each column of the data sector group is added with 16 rows of PO codes (Outer Code Parity), and each row of the data sector group is added with 10 bytes of PI codes (Inner Code Parity). Typically, the Read Solomon codes are employed as the PO codes and the PI codes. That is, the block code of 182 bytes (columns)×208 rows with the PO codes and the PI codes added are the Read Solomon product code referred to as an “ECC block”.

As shown in FIG. 18, interleaving (interchanging of rows) is performed within the ECC block to sequentially dispose 16 rows of the PO codes in every other row after each data sector added with the PI code. The data of 182 bytes×13 rows constituted by adding ten bytes of the PI code and one row of the PO code to one data sector are handled as a “recording sector”. After the 8-16 modulation, the NRZI conversion, etc. are performed for one block of the ECC block constituted by 16 recording sectors, recording to the optical disk is conducted.

Description will be made of a decoding process of receiving/regenerating the ECC block with reference to FIGS. 19, 20, and 21.

FIG. 19 shows a schematic configuration of an optical disk reproduction system. The optical disk reproduction system is constituted by an optical pickup 2 that optically reads the information (ECC block) recorded on an optical disk 1 such as a DVD medium, a front end processing unit 9 that performs an analog signal process such as binarization and synchronizing clock extraction based on the information read by the optical pickup 2, a decoding apparatus 11 that performs a decoding process such as the 8/16 demodulation and the error correction process based on the analog-processed data, a buffer memory 5 that is a working memory used in the course of the process in the decoding apparatus 11, and a host computer 7 that receives the data decoded by the decoding apparatus 11. The decoding apparatus 11 includes an error correcting apparatus 10 and the error correcting apparatus 10 is constituted by a buffer transferring unit 101, a PI/PO error correction processing unit 102, an EDC decoder 104, and a buffer transferring unit 105.

As shown in a flowchart of FIG. 20, a conventional error correction process flow in the error correcting apparatus 10 is as follows. First, reproduction data DIN corresponding to the 8/16-demodulated ECC block are buffered in the buffer transferring unit 101 and the whole reproduction data DIN are then stored in the buffer memory 5 (S200). A deinterleaving process is performed for the reproduction data DIN stored in the buffer memory 5.

The PI/PO error correction processing unit 102 reads the reproduction data DIN stored in the buffer memory 5 for each row of the ECC block (S201) and performs a detection correction process (hereinafter, PI detection correction process) based on the PI code added to each row of the ECC block in the reproduction data DIN (S202). On this occasion, the PI/PO error correction processing unit 102 stores position information of a symbol (bit) to which the PI detection correction process has been performed in the reproduction data DIN, which is a lost flag, into an internal register, etc. The reproduction data DIN′ after the PI detection correction process are stored in the buffer memory 5.

The PI/PO error correction processing unit 102 reads the reproduction data DIN′ stored in the buffer memory 5 for each column of the ECC block (S203) and performs a detection correction process (hereinafter, PO detection correction process) based on the PO code added thereto (S204). On this occasion, a lost correction process (hereinafter, PO lost correction process) may be performed using the lost flag of the PI detection correction process. The reproduction data DIN′ after the PO detection correction process or the PO lost correction process are stored in the buffer memory 5.

The EDC decoder 104 reads the reproduction data DIN′ stored in the buffer memory 5 for each data sector and performs error detection based on the EDC added thereto. A descrambling process is then performed for the reproduction data DIN″ stored in the buffer memory 5. The buffer transferring unit 105 reads the reproduction data DIN″ from the buffer memory 5, which are transferred as reproduction data OUT to the host computer 7.

With reference to Yoshizumi Eto and Toshinobu Kaneko “Error Correcting Code and Application thereof”, first edition, eighth printing, pp.183-188; Feb. 25, 2004; Ohmsha, Ltd., FIG. 21 shows a typical process flow of the PI/PO detection correction process described above. Japanese Patent Application Laid-Open Publication No. H11-41113 also discloses details of the PI/PO detection correction process and the PO lost correction process. As shown in FIG. 21, the PI/PO detection correction process is performed in the order of: the syndrome calculation for verifying whether an error exists or not (S210); derivation of an error position polynomial equation for obtaining a symbol position (hereinafter, error position) where an error occurs (S211); calculation of an error position obtained by substituting elements of a primitive polynomial defining a predetermined Galois field for the error position polynomial equation (S212) ; calculation of a value (magnitude) of an error obtained based on the syndrome, the error position, and the elements of the primitive polynomial defining the predetermined Galois field (S213); and final error correction (S214). The aforementioned lost flag is obtained in the calculation of an error position (S212).

By the way, in a conventional error correction process sequence for the block code (ECC block, etc.) combining at least two sets of the error correcting codes, the buffer memory, i.e., the working memory has been accessed every time the error correction process is performed based on each error correction code. For example, as shown in S201 and S203 of FIG. 20, all the data of the ECC block have been read from the buffer memory at both stages of the PI detection correction process and the PO detection correction process or the PO lost correction process. Such an access to the buffer memory is a bottleneck when speeding up the entire error correction process and, therefore, may pose a problem when further speeding up a whole system incorporating the conventional error correcting apparatus. For example, with regard to the HD DVD (High Definition DVD), etc., which recently draws attention as the next-generation DVD, further speeding up is requested in the data transfer rate of the reproduction data from the optical disk. However, in the arrangement of the conventional error correcting apparatus, faster data transfer may not be achieved for the reproduction data. To achieve faster data transfer of the reproduction data, it is conceivable to provide the PI/PO error correction processing unit as separate circuits to perform each process in parallel. However, in this case, it is problematic that the circuit scale is increased.

### SUMMARY OF THE INVENTION

In order to solve the above and other problems, according to an aspect of the present invention there is provided an error correcting apparatus receiving a block code constituted by first error correcting codes in the row direction and second error correcting codes in the column direction to two-dimensionally arranged data to perform an error correction process, the error correcting apparatus comprising a buffer memory that stores the block code; a syndrome calculating unit that performs syndrome calculations based on the first error correcting code in each row of the block code to generate a determination result indicating presence or absence of one or more errors in each row of the block code; a buffering unit that buffers the determination result; and a correction processing unit that performs a correction process based on the second error correcting code in each column of the block code read from the buffer memory and the determination result buffered in the buffering unit.

In order to solve the above and other problems, according to another aspect of the present invention there is provided an error correcting apparatus receiving a block code constituted by first error correcting codes in the row direction and second error correcting codes in the column direction to two-dimensionally arranged data to perform an error correction process, the error correcting apparatus comprising a buffer memory that stores the block code; a syndrome calculating unit that performs syndrome calculations based on the first error correcting code in each row of the block code to generate a determination result indicating presence or absence of one or more errors in each row of the block code; a buffer transferring unit that buffers and transfers the determination result to the buffer memory; a buffering unit that buffers the determination result read from the buffer memory; and a correction processing unit that performs a correction process based on the second error correcting code in each column of the block code read from the buffer memory and the determination result buffered in the buffering unit.

### BRIEF DESCRIPTION OF THE DRAWINGS

The above and other aspects, features and advantages of the present invention will become more apparent from the following detailed description when taken in conjunction with the accompanying drawings, in which:

FIG. 1 shows a configuration of an optical disk reproduction system including an error correcting apparatus according to the present invention;

FIG. 2 shows a configuration of an error correcting apparatus according to the first implementation of the present invention;

FIG. 3 is a flowchart of a process flow of the error correcting apparatus according to the first implementation of the present invention;

FIGS. 4A to 4D are timing charts of process flows of the error correcting apparatus according to the first implementation of the present invention;

FIG. 5 shows a configuration of a bitmap-type error flag buffering unit according -to the first implementation of the present invention;

FIG. 6 shows a state of a shift register in the bitmap-type error flag buffering unit according to the first implementation of the present invention;

FIGS. 7A to 7F are timing charts of process flows of the bitmap-type error flag buffering unit according to the first implementation of the present invention;

FIG. 8 shows a configuration of a pointer-type error flag buffering unit according to the first implementation of the present invention;

FIG. 9 shows states of a RAM and a counter in the pointer-type error flag buffering unit according to the first implementation of the present invention;

FIG. 10 shows a configuration of an error correcting apparatus according to a second implementation of the present invention;

FIG. 11 is a flowchart of a process flow of the error correcting apparatus according to the second implementation of the present invention;

FIGS. 12A to 12D are timing charts of process flows of the error correcting apparatus according to the second implementation of the present invention;

FIGS. 13A to 13E show access statuses to the buffer memory of the error correcting apparatus according to the second implementation of the present invention;

FIG. 14 shows a configuration of a bitmap-type error flag buffering unit according to the second implementation of the present invention;

FIG. 15 shows a configuration of a pointer-type error flag buffering unit according to the second implementation of the present invention;

FIG. 16 is a diagram for describing a format of a data sector of the DVD standard;

FIG. 17 is a diagram for describing a format of an ECC block of the DVD standard;

FIG. 18 is a diagram for describing a format of the ECC block of the DVD standard;

FIG. 19 shows a configuration of an optical disk reproduction system including a conventional error correcting apparatus

FIG. 20 is a flowchart of a process flow of the conventional error correcting apparatus; and

FIG. 21 is a flowchart of a conventional PI/PO error correction process flow.

### DETAILED DESCRIPTION OF THE INVENTION

At least the following matters will be made clear by the explanation in the present specification and the description of the accompanying drawings.

Configuration of Optical Disk Reproduction System

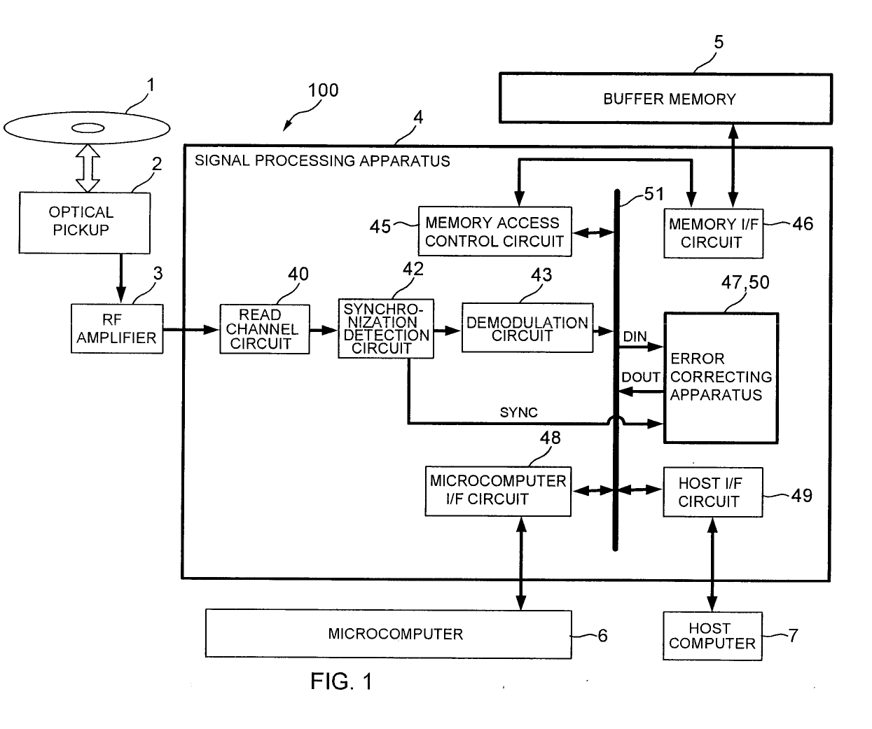

FIG. 1 shows a configuration of an optical disk reproduction system by way of example of a system including an “error correcting apparatus” according to the present invention. The optical disk reproduction system of the implementation is described as a DVD reproduction system. Therefore, in the optical disk reproduction system of the implementation, an error correction process is performed by receiving one-block reproduction data (“block code”) based on the Read Solomon product code that combines a PI code (“first error correcting code”) in the row direction and a PO code (“second error correcting code”) in the column direction relative to a two-dimensionally arranged data sector group. Of course, the optical disk reproduction system according to the present invention may be a CD reproduction system or a HD-DVD reproduction system.

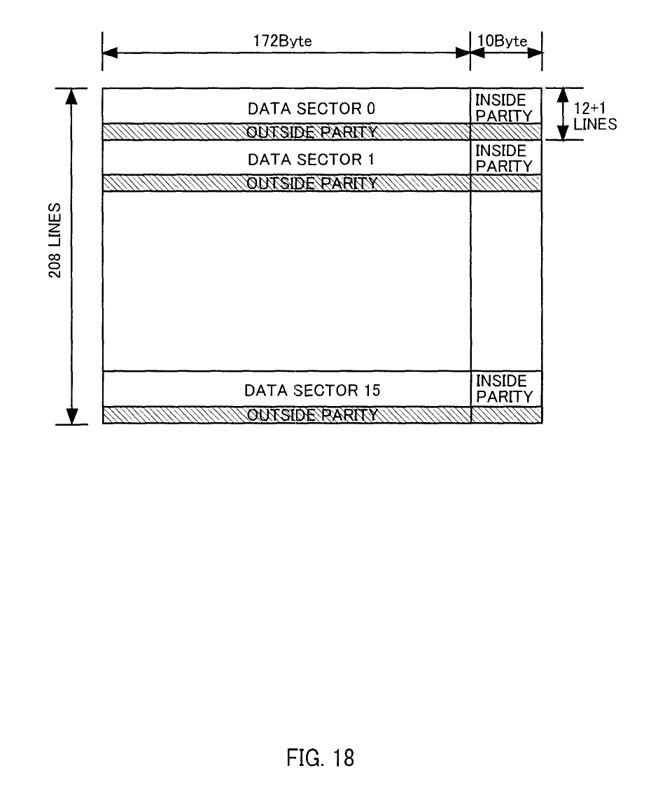

An optical disk 1 is a DVD medium such as DVD±R/RW, DVD-RAM, and DVD-ROM, and information is recorded in accordance with the data format of the ECC block shown in FIG. 18. In various pre-format modes, the optical disk 1 records the ECC block, 16 data sectors constituting the ECC block, 26 frames constituting the data sector, and various sync signals SYNC indicating each beginning in advance.

An optical pickup 2 irradiates the optical disk 1 with a laser beam and receives reflected light to optically read the information recorded in the optical disk 1.

An RF amplifier 3 is an amplifier that amplifies the information read by the optical pickup 2. The RF amplifier 3 is provided with an AGC (Automatic Gain Control) function for adjusting the gain automatically.

A signal processing apparatus 4 executes various signal processes relating to the optical disk reproduction for the output of the RF amplifier 3 and is provided as one or a plurality of semiconductor integrated circuits.

A buffer memory 5 is a working memory used in the course of the execution of the error correction process according to the present invention and is an external memory of the signal processing apparatus 4. That is, the buffer memory 5 stores each block of data that are a target of the error correction process depending on the output of the RF amplifier 3. Typically, a DRAM, etc. are employed for the buffer memory 5.

A microcomputer 6 is a system controller responsible for the overall control of the optical disk reproduction system.

A read channel circuit 40 binarizes the output of the RF amplifier 3 and generates a reference clock signal. In the case of the DVD-ROM standard, the HD-DVD standard, etc., the read channel circuit 40 also performs the PR equivalent process or the Viterbi decoding process based on the PRML (Partial Response Maximum Likelihood) mode.

A synchronization detection circuit 42 generates the aforementioned sync signal SYNC based on the binarized signal and the reference clock signal generated by the read channel circuit 40. The sync signal SYNC is transmitted to error correction circuit (47, 50).

A demodulation circuit 43 generates 8/16-demodulated data (hereinafter, reproduction data DIN) by performing a demodulation process of the 8/16 modulation for the binarized signal through the synchronization detection circuit 42. The reproduction data DIN are transmitted to the error correcting apparatus (47, 50) via an internal bus 51.

The error correcting apparatus (47, 50) performs the error correction process for the reproduction data DIN. After the error correction process, the processed reproduction data DIN (hereinafter, reproduction data DOUT) are transmitted to a host computer 7 via a host I/F circuit 49 described later. The internal configuration and operation of the error correcting apparatus (47, 50) will be described in detail later.

A memory access control circuit 45 generates read/write commands, addresses, etc. corresponding to the buffer memory 5 in response to a request for access to the buffer memory 5 from the error correcting apparatus (47, 50).

A memory I/F circuit 46 is a communication interface circuit for communicably connecting the error correcting apparatus (47, 50) and the buffer memory 56 via the memory access control circuit 45. For example, a three-wire serial interface is employed for the memory I/F circuit 46.

A microcomputer I/F circuit 48 is a communication interface circuit for communicably connecting the signal processing apparatus 4 and the microcomputer 6. For example, a UART (Universal Asynchronous Receiver and Transmitter), a three-wire serial interface, an I2C bus interface, etc. are employed for the microcomputer I/F circuit 48.

The host I/F circuit 49 is a communication interface circuit for communicably connecting the signal processing apparatus 4 and the host computer 7. Typically, an ATAPI (Attachment Packet Interface) is employed for the host I/F circuit 49.

First Embodiment: Error Correcting Apparatus

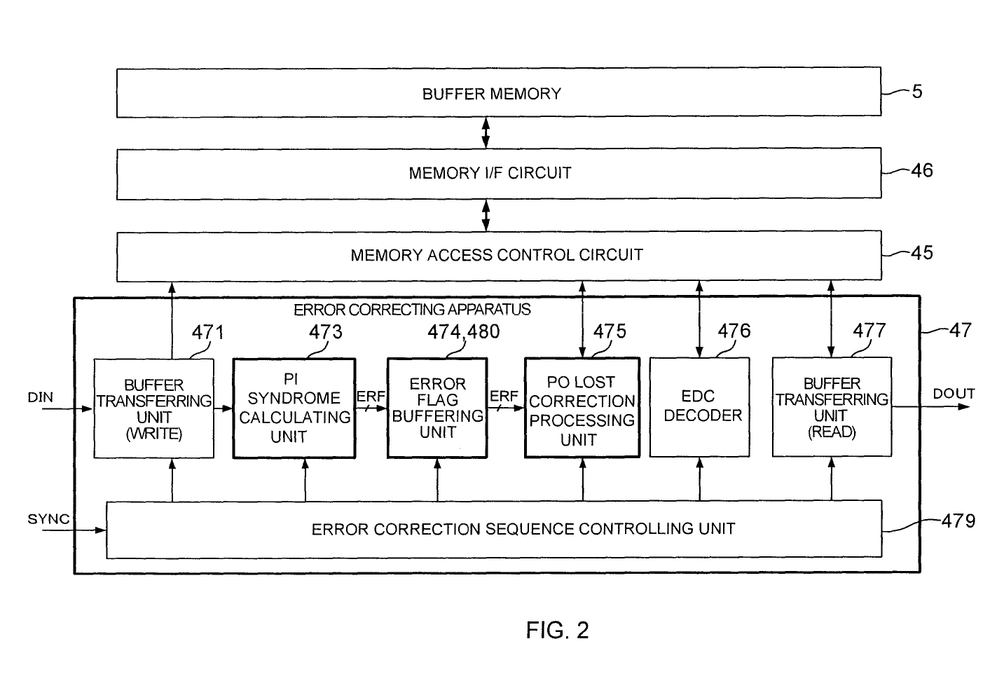

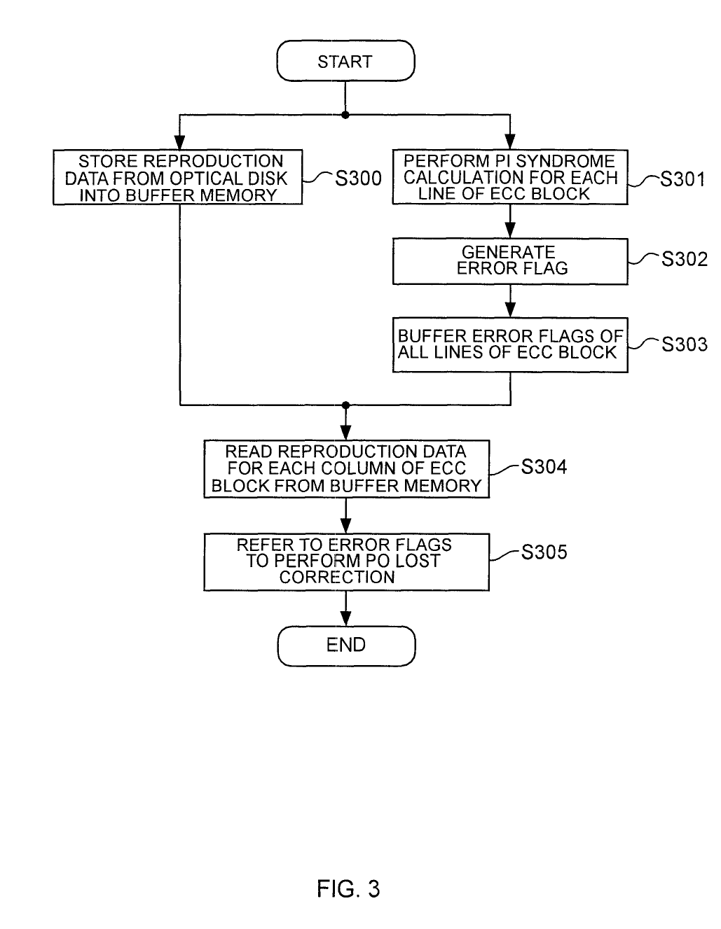

Description will be made of the “error correcting apparatus 47” according to a first implementation of the present invention with reference to FIG. 2 as well as FIG. 3 as needed. For convenience of explanation, description will not be made of the deinterleaving process typically performed before the PI syndrome calculation described later and the descrambling process typically performed after the error detection process described later.

A buffer transferring unit 471 buffers one block of the reproduction data DIN (hereinafter, ECC block) received from demodulation circuit 43 via the internal bus 51 and transfers the ECC block to the buffer memory 5 via the memory access control circuit 45 and the memory I/F circuit 46. As a result, the ECC block is written into the buffer memory 5 (S300). In concurrence with the transfer of the ECC block to the buffer memory 5, the buffer transferring unit 471 transfers the same ECC block to a PI syndrome calculating unit 473.

The PI syndrome calculating unit 473 sequentially performs syndrome calculation (hereinafter, PI syndrome calculation) of the ECC block transferred from the buffer transferring unit 471 based on the PI code added to each row (S301). That is, the PI syndrome calculation is performed in concurrence with the writing of the ECC block into the buffer memory 5.

In an example of the PI syndrome calculation, for example, in the case of a (8, 4) Read Solomon code with a code length of “8” and an information number of “4”, if the reproduction data DIN of an arbitrary row of the ECC block are represented by (D3, D2, D1, D0, P3, P2, P1, P0: where D3 to D0 are symbols and P3 to P0 are PI codes), syndromes S0 to S3 defined by the following equations (1) to (4) are calculated. αˆn (natural number) is an element of a primitive polynomial defining the Galois field GF (2ˆ3).
S0=D3+D2+D1+D0+P3+P2+P1+P0 (1)
S1=αˆ7·D3+αˆ6·D2+αˆ5·D1+αˆ4·D0+αˆ3·P3+αˆ2·P2+αˆ1·P1+P0 (2)
S2=αˆ14·D3+αˆ12·D2+αˆ10·D1+αˆ8·D0+αˆ6·P3+αˆ4·P2+αˆ2·P1+P0 (3)
S3=αˆ21·D3+αˆ18·D2+αˆ15·D1+αˆ12·D0+αˆ9·P3+αˆ6·P2+αˆ3·P1+P0 (4)

If an error does not occur in the symbols D3 to D0, all the syndromes S0 to S3 are “0”. On the other hand, if an error occurs in the symbols D3 to D0, a value different from “0” is obtained for the syndromes S0 to S3. For example, if an error with magnitude of e2 is added to the symbol D2, the syndrome S0 is e2; the syndrome S1 is αˆ6·e2; the syndrome S2 is αˆ12·e2; and the syndrome S3 is αˆ18·e2.

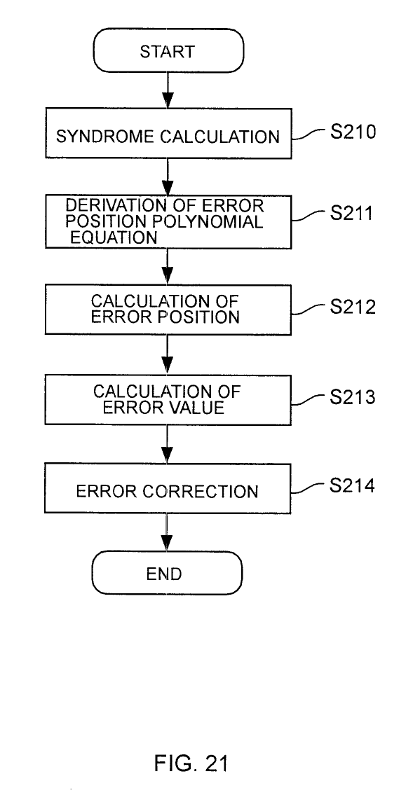

The PI syndrome calculating unit 473 can determine whether an error occurs or not for each row of the ECC block due to the result of the PI syndrome calculation defined in advance. The PI syndrome calculating unit 473 generates an error flag ERF showing the result of the determination of the presence or absence of the error for each row of the ECC block sequentially (S302). The error flag ERF is used in a PO lost correction process described later and has contents different from the lost flag used in the conventional lost correction process. That is, while the conventional lost flag is obtained through the derivation of the error position polynomial equation (S211) and the calculation of the error position (S212) shown in FIG. 21, the error flag ERF is obtained simply from the result of the PI syndrome calculation only.

An error flag buffering unit 474 (“buffering unit”) is constituted mainly by a plurality of bitmap registers and buffers the error flags ERF of all the rows of the ECC block, which are sequentially generated by the PI syndrome calculating unit 473 (S303). The bitmap register is an aggregate of one-bit memory elements for the predetermined number of bits and the ERF of all the rows of the ECC block is stored in the one-bit memory elements in a bit-mapped manner. In this implementation, a shift register is employed as the bitmap register, which stores the error flags ERF of all the rows of the ECC block in shift operation. Other than the shift register, a RAM may be employed as the bitmap register, which stores the error flags ERF of all the rows of the ECC block in random access. The mode of buffering the error flags ERF with the use of the bitmap register is hereinafter referred to as a “bitmap type”.

An error flag buffering unit 480 (“buffering unit”) is another implementation of the error flag buffering unit 474, is constituted mainly by a plurality of RAMs (“error-row pointer storing memories”), and buffers PI error-row numbers ELN (“error-row pointers”) that indicate the ECC block rows corresponding to the error flags ERF indicating the presence of the error among the error flags ERF sequentially generated by the PI syndrome calculating unit 473. The mode of buffering the PI error-row number ELN with the use of the RAM, etc. is hereinafter referred to as a “pointer type”.

A PO lost correction processing unit 475 reads each column of the ECC block written into the buffer memory 5 via the memory access control circuit 45 and the memory I/F circuit 46 (S304). The PO lost correction processing unit 475 performs the lost correction process (hereinafter, PO lost correction process) for each column of the ECC block based on the PO code added to each column of the ECC block and the error flags ERF of all the rows of the ECC block buffered in the error flag buffering unit 474 or the PI error-row numbers ELN for one block buffered in the error flag buffering unit 480. The ECC block after the PO lost correction process is written into the buffer memory 5 again.

Specifically, the PO lost correction processing unit 475 refers to the error flags ERF of all the rows of the ECC block or the PI error-row numbers ELN for one block, which are the result of the PI syndrome calculation, and considers that the lost correction position is a bit of a row corresponding to the effort flag ERF indicating the presence of the error among the 208-bit reproduction data DIN for one column of the ECC flag. That is, the lost correction position has been known in advance without the derivation of the error position polynomial equation and the calculation of the error position. Therefore, the PO lost correction processing unit 475 may perform only the calculation of an error value and the error correction using the error value based on the error flags ERF of all the rows of the ECC block or the PI error-row numbers ELN for one block. For example, in the case of the aforementioned example, the error value E2 can be obtained by calculating only the syndrome S0 of Equation (1). The error correction can be performed by subtracting the error value E2 from the value of the symbol D2 corresponding to the syndrome S0 of Equation (1).

An EDC decoder 476 reads the ECC block after the PO lost correction process from the buffer memory 5 and performs an error detection process based on the EDC added to each data sector to verify the error correction of the PO lost correction process. The verification result is written into the buffer memory 5.

A buffer transferring unit 477 reads the ECC block after the PO lost correction process from the buffer memory 5 and transfers the ECC block as the reproduction data DOUT to the host computer 7 via host I/F circuit 49.

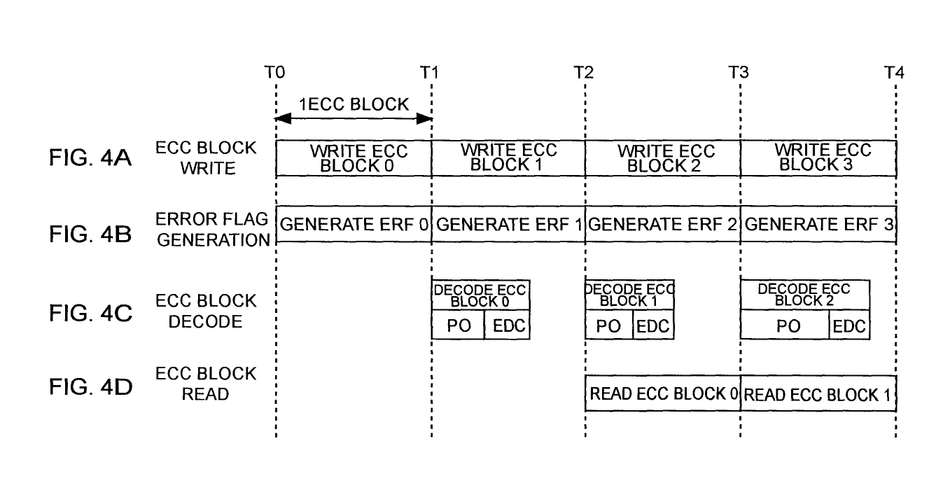

An error correction sequence controlling unit 479 identifies the beginnings of the ECC block and the data sector based on the sync signal generated by the synchronization detection circuit 42 to perform the sequence control of the error correction process according to the present invention for each processing unit (471, 473, (474, 478), 475, 476, 477). As shown in FIGS. 4A to 4D, the processes of the processing units are synchronized.

FIGS. 4A to 4D are timing charts of the error correction process of the error correction apparatus 47. FIG. 4A shows a flow of a writing process from the buffer transferring unit 471 to the buffer memory 5; FIG. 4B shows a flow of a generating process of the error flag ERF in the PI syndrome calculating unit 473; FIG. 4C shows a flow of a decoding process combining the PO lost correction process in the PO lost correction processing unit 475 and the error detection process of the EDC decoder 476; and FIG. 4D shows a flow of a reading process from the buffer memory 5 to the buffer transferring unit 477 after the decoding process.

In one block period from time T0 to T1, a parallel process is performed for writing an ECC block 0 from the buffer transferring unit 471 to the buffer memory 5 and generating the error flag ERF of the ECC block 0 in the PI syndrome calculating unit 473.

In one block period from time T1 to T2, a parallel process is performed for writing an ECC block 1 from the buffer transferring unit 471 to the buffer memory 5 and generating the error flag ERF of the ECC block 1 in the PI syndrome calculating unit 473.

In one block period from time T2 to T3, a parallel process is performed for writing an ECC block 2 from the buffer transferring unit 471 to the buffer memory 5 and generating the error flag ERF of the ECC block 2 in the PI syndrome calculating unit 473. The decoding process of the ECC block 1 is performed in the PO lost correction processing unit 475 and the EDC decoder 476. The reading process of the ECC block 0 is also performed from the buffer memory 5 to the buffer transferring unit 477.

After time T3, the same process is performed as the one block period from time T2 to T3.

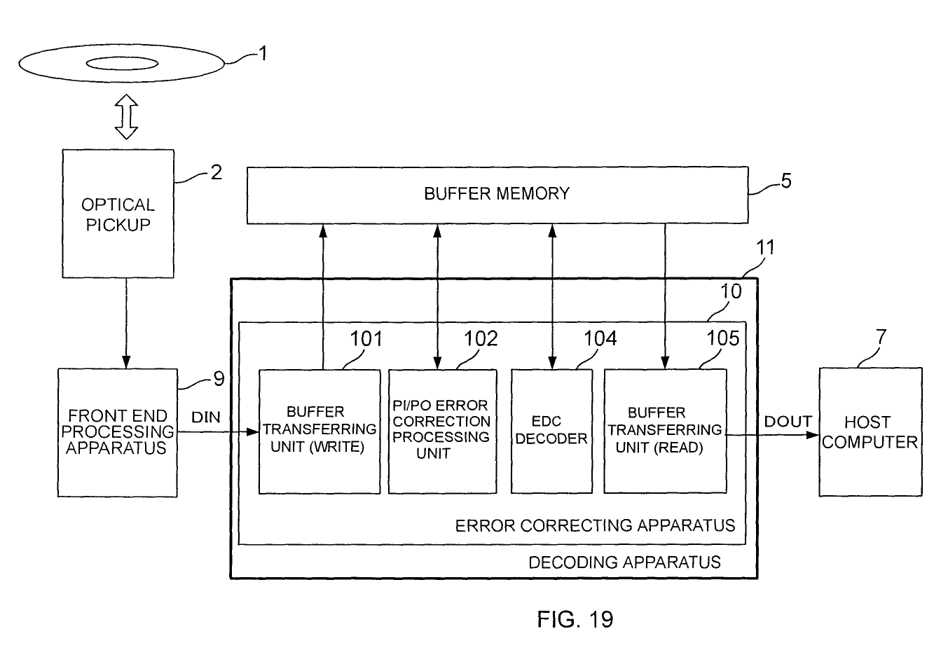

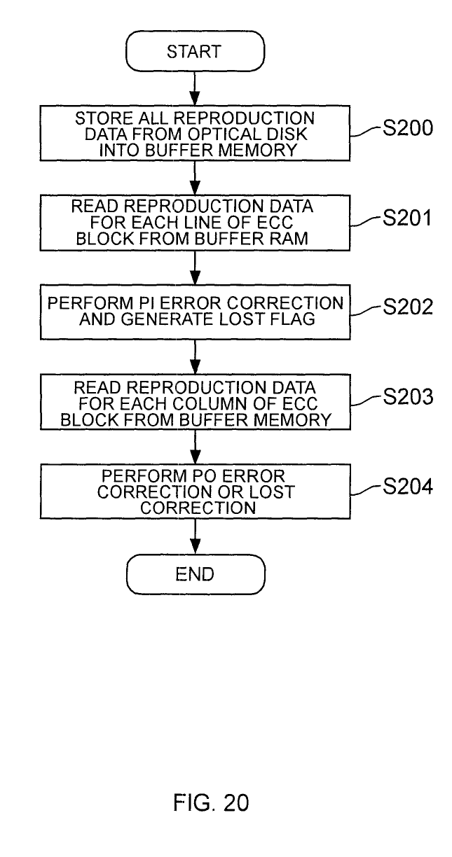

In this way, in the error correcting apparatus 47, the PO lost correction processing unit 475 accesses the buffer memory 5 and the PI syndrome calculating unit 473 does not access the buffer memory 5. That is, as compared to the conventional error correcting apparatus 10 shown in FIG. 19 that accesses to the buffer memory 5 every time the PI detection correction process and the PO detection correction process (or PO lost correction process) are performed, the error correcting apparatus 47 according to the present invention reduces the number of accesses to the buffer memory 5 in the entire error correction process. Therefore, the error correction process according to the present invention can follow the data transfer rate requested in the optical disk reproduction and can easily achieve the real time process without the latency time associated with the access to the buffer memory 5.

In concurrence with the writing process from the buffer transferring unit 471 to the buffer memory 5, the PI syndrome calculating unit 473 performs the PI syndrome calculation process. That is, as compared to the writing process of the ECC block to the buffer memory 5 in the conventional buffer transferring unit 101 and the PI detection correction process in the conventional PI error correction processing unit, which are processed serially as shown in FIG. 19, since the present invention performs a parallel process for the writing process of the ECC block to the buffer memory 5 in the buffer transferring unit 471 and the PI syndrome calculation process in the PI syndrome calculating unit 473, the speeding up can be achieved in the entire error correction process.

The PI syndrome calculating unit 473 performs only the PI syndrome calculation. That is, as compared to the conventional PI error correction processing unit 102 shown in FIG. 19 that follows the procedures of the derivation of the error position polynomial equation (S211), the calculation of the error position (S212), the calculation of the error value (S213), and the error correction (S214) in addition to the syndrome calculation (S210) as shown in FIG. 21, since the PI syndrome calculating unit 473 according to the present invention performs only the PI syndrome calculation, the process burden can be alleviated and the speeding up can be achieved in the entire error correction process. As compared to the conventional PI error correction processing unit 102, the circuit scale is reduced in the PI syndrome calculating unit 473 according to the present invention.

The PO lost correction processing unit 475 refers to the error flag ERF generated in the PI syndrome calculating unit 473 to perform the PO lost correction process. That is, the lost correction process is performed which is known as the process with a twofold error correction capability relative to the detection correction process since the error position is found in advance. Therefore, the error correction process according to the invention can follow the faster data transfer rate of the reproduction data DIN from the optical disk 1 and can easily achieve the real time process while ensuring the error correction capability with appropriate quality.

Bitmap-Type Error Flag Buffering Unit

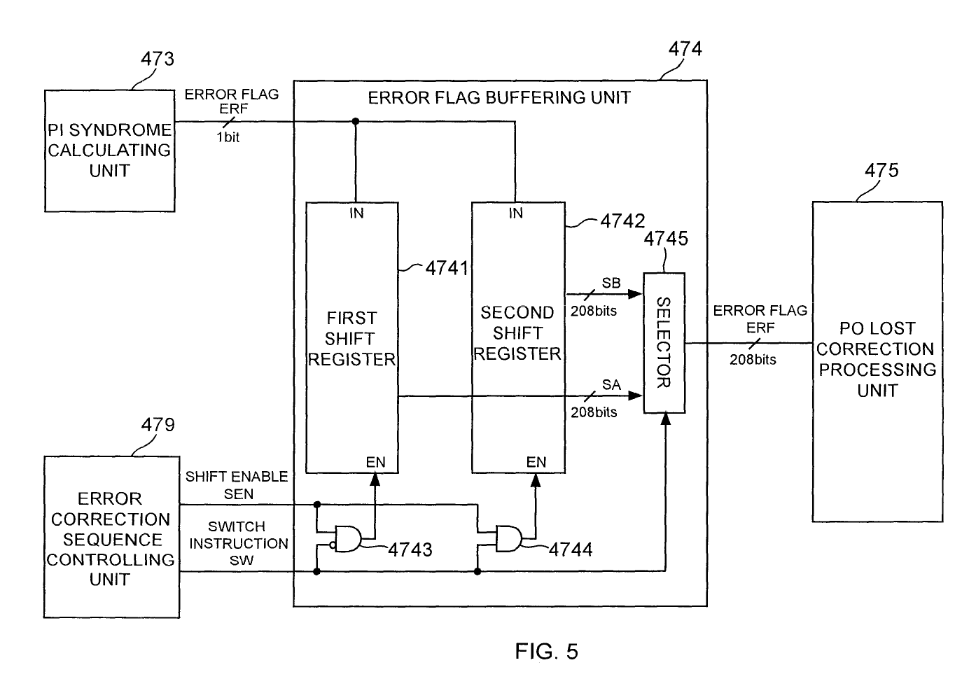

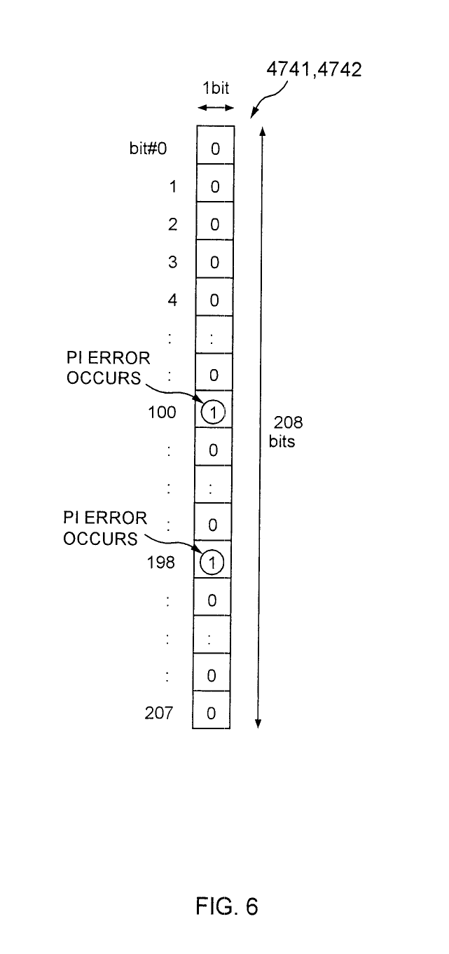

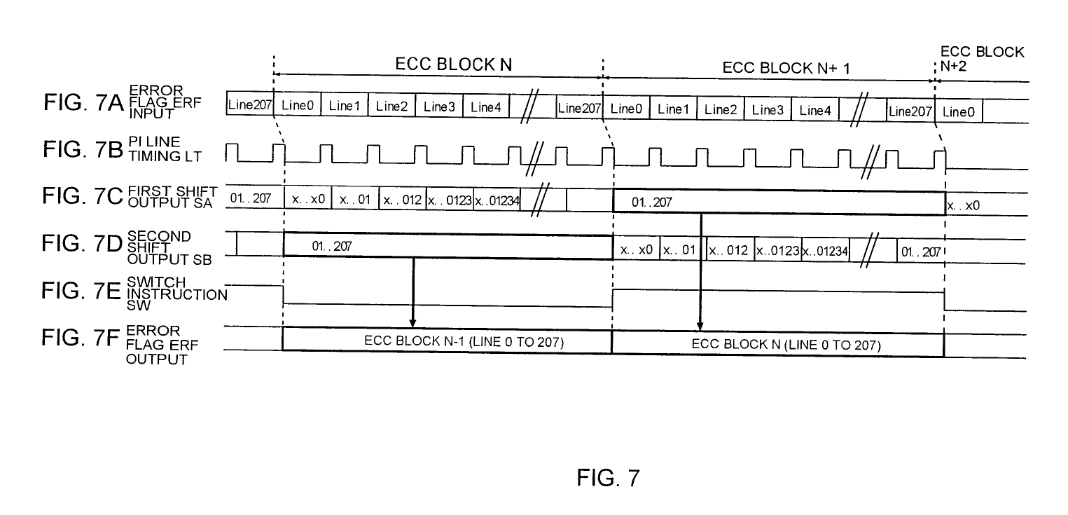

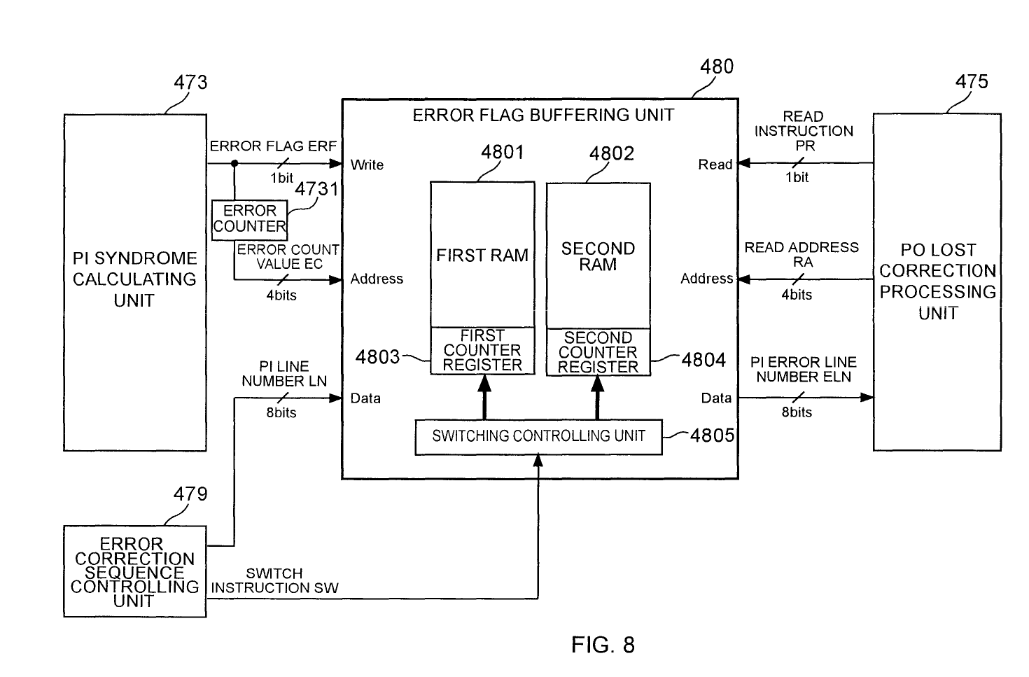

Description will be made of the configuration and operation of the bitmap-type error flag buffering unit 474 with reference to FIG. 5 as well as FIGS. 6 and 7A to 7F as needed.

A first shift register 4741 and a second shift register 4742 receive the error flags ERF (see FIG. 7A) of all the rows of the ECC block (208 bits) and a PI row timing signal LT (see FIG. 7B) for identifying each row of the ECC block in synchronization with the error flag ERF of each row of the ECC block.

The first shift register 4741 and the second shift register 4742 use the PI row timing signal LT as a shift clock signal to buffer the error flags ERF of all the rows of the ECC block. When the error flags ERF of all the rows of the ECC block are buffered, the first shift register 4741 and the second shift register 4742 transmit to a selector 4745 a first shift output SA (see FIG. 7C) and a second shift output SB (see FIG. 7D), which are the error flags ERF of all the rows of the ECC block stored respectively.

FIG. 6 shows that the error flags ERF of all the rows of the ECC block are buffered in the first shift register 4741 and the second shift register 4742. FIG. 6 shows an example that errors occur in the 100th row and the 198th row of the ECC block. In this case, the PO lost correction processing unit 475 performs the PO lost correction relating to the 100th row and the 198th row of the ECC block.

By the way, although two sets of the first shift register 4741 and the second shift register 4742 are provided in the implementation, two sets are not a limitation and three sets or more may be provided. As the number of the shift register is increased, a larger margin is provided in the dissociation between the buffering process of the error flags ERF into the shift register and the PO lost correction process.

AND elements 4743, 4744 are one implementation of a “switching controlling unit” according to the present invention. The AND elements 4743, 4744 receive a shift enable signal SEN and a switch instruction SW from the error correction sequence controlling unit 479 to perform respective AND calculations. The output of the AND element 4743 is handled as an enable signal in the first shift register 4741 and the output of the AND element 4744 is handled as an enable signal in the second shift register 4742.

When the shift enable signal SEN and the switch instruction SW are “H, L”, since each output of the AND elements 4743, 4744 is “H, L”, the first shift register 4741 becomes the Enable state that enables the shift operation and the second shift register 4742 becomes the Disable state that disables the shift operation. When the shift enable signal SEN and the switch instruction SW are “H, H”, since each output of the AND elements 4743, 4744 is “H, L”, the first shift register 4741 becomes the Disable state and the second shift register 4742 becomes the Enable state. When the shift enable signal SEN is “L”, the first and second shift registers 4741, 4742 become the Disable state regardless of the switch instruction SW. In this way, the Enable states of the first and second shift registers 4741, 4742 are switched by the AND elements 4743, 4744 in a complementary manner.

The selector 4745 uses the switch instruction SW (see FIG. 7E) received from the error correction sequence controlling unit 479 as a selector control signal to select and output one of the first shift output SA received from the first shift register 4741 and the second shift output SB received from the second shift register 4742 to the PO lost correction processing unit 475 (see FIG. 7F). As a result, the PO lost correction processing unit 475 refers to the first shift output SA or second shift output SB to perform the PO lost correction process.

That is, the AND elements 4743, 4744 serially switches the first shift register 4741 and the second shift register 4742 for the buffering of the error flags ERF of all the rows of the ECC block from the PI syndrome calculating unit 473 and for the lost correction process in the lost correction processing unit 475. As a result, a pipeline process is performed for the buffering process of the error flags ERF of all the rows of the ECC block and the PO lost correction process.

In this way, the bitmap-type error flag buffering unit 474 performs the pipeline process for the buffering process of the error flags ERF of all the rows of the ECC block and the PO lost correction process to achieve the speeding up of the entire error correction process according to the invention.

Pointer-Type Error Flag Buffering Unit

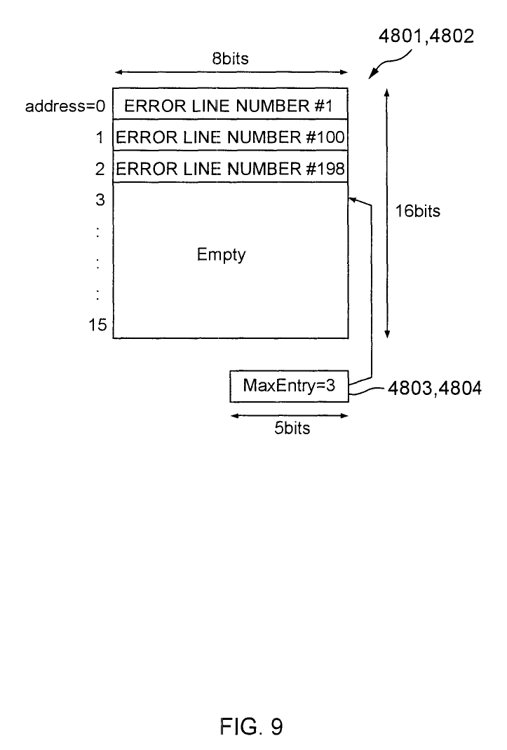

Description will be made of the configuration and operation of the pointer-type error flag buffering unit 480 with reference to FIG. 8 as well as FIG. 9 as needed.

The error flag buffering unit 480 receives from the PI syndrome calculating unit 473 the error flags ERF of each row of the ECC block, a PI row number LN that is a pointer indicating a row of the ECC block corresponding to each error flag ERF, and an error count value EC that is the number of rows including an error counted by an error counter 4731.

If one error flag ERF received from the PI syndrome calculating unit 473 indicates the presence of the error, the error flag buffering unit 480 uses the error count value EC received in synchronized with the error flag ERF as a write address to buffer the PI row number LN also received in synchronized with the error flag ERF, i.e., the PI error-row number ELN (“error-row pointer”) indicating the presence of the error into a first RAM 4801 and a second RAM 4802.

At the execution timing of the PO lost correction process in the PO lost correction processing unit 475, the error flag buffering unit 480 receives from the PO lost correction processing unit 475 a read instruction PR and a read address RA for the first RAM 4801 and the second RAM 4802. As a result, the PI error-row number ELN buffered in the first RAM 4801 and the second RAM 4802 is read and transmitted to the PO lost correction processing unit 475. As a result, the PO lost correction processing unit 475 performs the PO lost correction process while referring to the PI error-row number ELN received from the error flag buffering unit 480.

The first RAM 4801 and the second RAM 4802 are one implementation of an “error-row pointer storing memory” according to the present invention and are memories that buffer the PI error-row number ELN. It is known that the lost correction cannot be performed when errors occur in more than “16” rows of all the rows of the ECC block. Therefore, “16 bits×bit number of PI error-row number ELN (e.g., 8 bits)” is sufficient for the storage capacities of the first RAM 4801 and the second RAM 4802.

By the way, although two sets of the first RAM 4801 and the second RAM 4802 are provided in the implementation, two sets are not a limitation and three sets or more may be provided. As the number of the RAM is increased, a larger margin is provided in the dissociation between the buffering process of the PI error-row number ELN into the RAM and the PO lost correction process.

A first counter register 4803 and a second counter register 4804 store the error count value EC that indicates the number of the PI error-row numbers ELN written into the first RAM 4801 and the second RAM 4802, respectively. That is, the error count value EC identifies to which write address the PI error-row numbers ELN are written out of all the addresses of the first RAM 4801 and the second RAM 4802 and indicates the beginning address of the Empty region. When the count value reaches the maximum count value “16” that enables the lost correction, the error flag buffering unit 480 prohibits the writing of the PI error-row number ELN to the first RAM 4801 and the second RAM 4802.

FIG. 9 shows the state when the PI error-row numbers ELN are written into the first RAM 4801 and the second RAM 4802, and the state of the first counter register 4803 and the second counter register 4804 in this case. In the example shown in FIG. 9, errors have been occurred in three rows, which are the first row, the 100th row, and the 198th row, among all the rows of the ECC block. In this case, in the first RAM 4801 and the second RAM 4802, the PI error-row numbers ELN are written in sectioned regions at addresses 0 to 2 and sectioned regions at addresses 3 to 15 are the Empty region. The error count value EC stored in the first counter register 4803 and the second counter register 4804 is “3”, which indicates the beginning address of the Empty region.

A switching controlling unit 4805 performs control based on the switch instruction SW received from the error correction sequence controlling unit 479 to connect one of the first RAM 4801 and the second RAM 4802 with the PI syndrome calculating unit 473 and to connect the other with the PO lost correction processing unit 475. That is, the switching controlling unit 4805 switches each of the first RAM 4801 and the second RAM 4802 for the buffering of the PI error-row numbers ELN and for the lost correction process.

As a result, a pipeline process is performed for the buffering process of the PI error-row numbers ELN and the PO lost correction process to achieve the speeding up of the entire error correction process according to the invention. As compared to the bitmap-type error flag buffering unit 474, the circuit scale is reduced in the pointer-type error flag buffering unit 480.

Second Embodiment: Error Correcting Apparatus

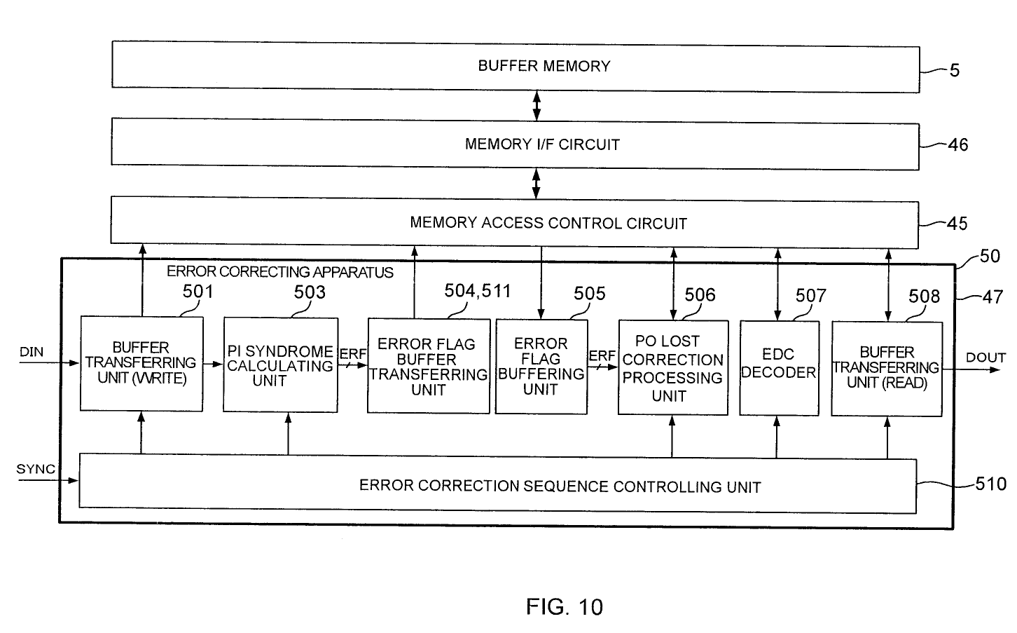

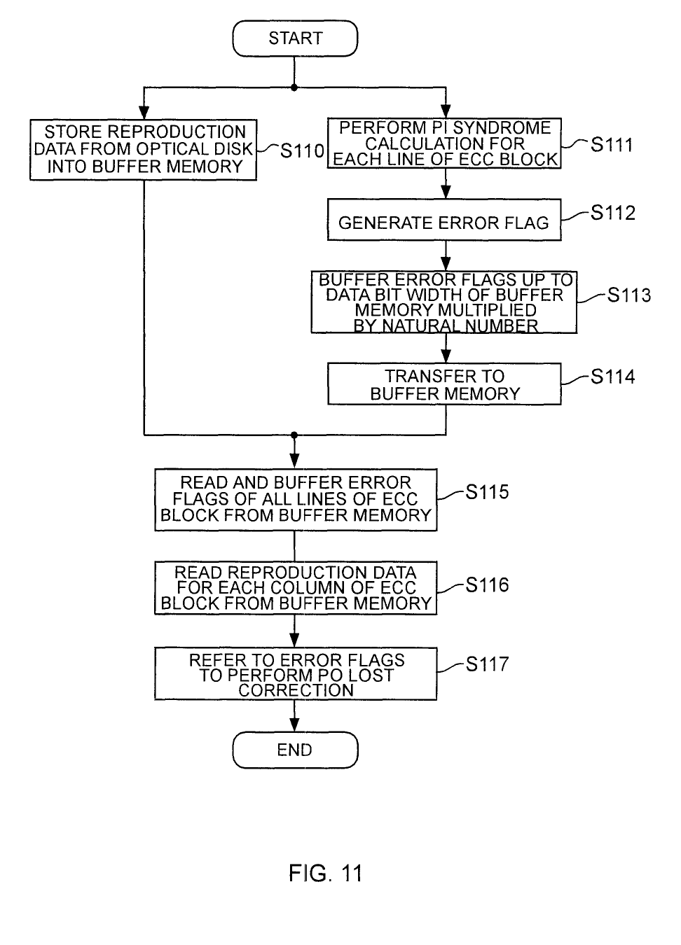

Description will be made of the “error correcting apparatus 50” according to a second implementation of the present invention with reference to FIG. 10 as well as FIG. 11 as needed. For convenience of explanation, description will not be made of the deinterleaving process typically performed before the PI syndrome calculation and the descrambling process typically performed after the error detection process, as is the case with the error correcting apparatus 47 according to the first implementation of the present invention.

As compared to the error correcting apparatus 47 according to the first implementation of the present invention, the error correcting apparatus 50 according to the second implementation of the present invention has differences only in an error flag buffer transferring unit (504, 511) and an error flag buffering unit 505.

The error flag buffer transferring unit 504 (“buffer transferring unit”) is the bitmap type, which is constituted mainly by a plurality of shift registers (bitmap registers), and buffers the error flags ERF sequentially generated by a PI syndrome calculating unit 503. The error flag buffering unit 505 is the pointer type, which is constituted mainly by a plurality of RAMs, and buffers the PI error-row numbers ELN (“error-row pointers”) that indicate the ECC block rows corresponding to the error flags ERF indicating the presence of the error among the error flags ERF sequentially generated by the PI syndrome calculating unit 503. When the error flags ERF or the PI error-row numbers ELN are buffered up to the data bit width of the buffer memory 5 multiplied by a predetermined natural number (S113), the error flag buffer transferring unit (504, 511) performs the buffer transfer to the buffer memory 5 (S114).

The error flag buffering unit 505 (“buffering unit”) buffers the error flags ERF of all the rows of the ECC block or the PI error-row numbers ELN of one block read from the buffer memory 5 (S115). The error flag buffering unit 505 is configured to be the bitmap type or the pointer type, as is the case with the error flag buffering units 474, 480 of the first implementation according to the present invention.

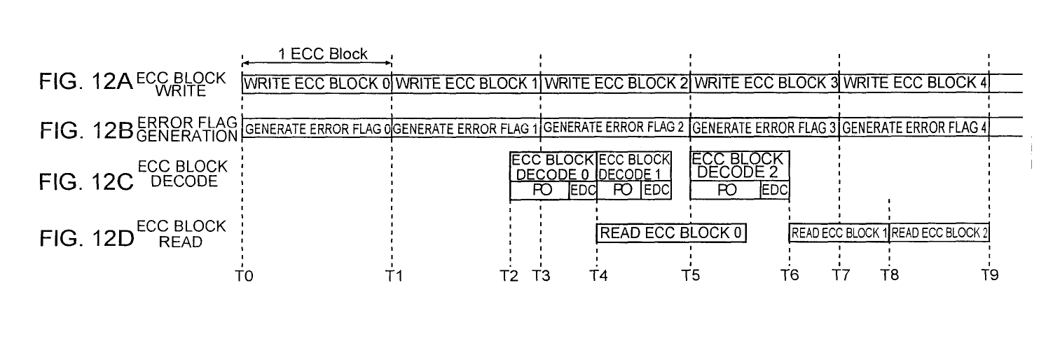

The error flags ERF of all the rows of the ECC block or the PI error-row numbers ELN of one block are written once into the buffer memory 5 by the error flag buffer transferring unit (504, 511). Therefore, as shown in FIG. 12, an asynchronous relationship is created between each process in a buffer transferring unit 501 and the PI syndrome calculating unit 503 and each process in a PO lost correction processing unit 506, an EDC decoder 507, and a buffer transferring unit 508.

FIGS. 12A to 12D are timing charts of the error correction process of the error correcting apparatus 50. The description of FIGS. 12A to 12D is the same as the FIGS. 4A to 4D.

In one block period from time T0 to T1, a parallel process is performed for writing an ECC block 0 from the buffer transferring unit 501 to the buffer memory 5 and generating the error flag ERF of the ECC block 0 in the PI syndrome calculating unit 503.

In one block period from time T1 to T3, a parallel process is performed for writing an ECC block 1 from the buffer transferring unit 501 to the buffer memory 5 and generating the error flag ERF of the ECC block 1 in the PI syndrome calculating unit 503.

Before time T2 during one block period from time T1 to T3, the error flag buffering unit 505 completes the buffering of the error flags 0 of all the rows of the ECC block 0 or the PI error-row numbers ELN of the ECC block 0.

Therefore, at time T2, the decoding process of the ECC block 0 is performed asynchronously in the PO lost correction processing unit 475 and the EDC decoder 476 without waiting the writing of the ECC block 2 to the buffer memory 5 and the generation of the error flags ERF in the PI syndrome calculating unit 503 at time 3. At time T4 when the decoding process of the ECC block 0 is terminated, the decode process of the next ECC block 1 is performed in the PO lost correction processing unit 475 and the EDC decoder 476 and the ECC block 0 is read from the buffer memory 5 to the buffer memory 508.

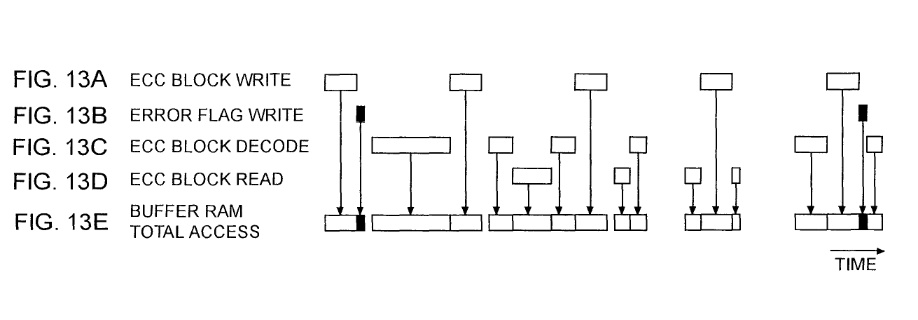

FIGS. 13A to 13E show access statuses to the buffer memory 5 from each processing unit (501, 503, (504, 511), 505, 506, 507, 508). FIG. 13A shows the write access for the ECC block from the buffer transferring unit 501 to the buffer memory 5; FIG. 13B shows the write access for the error flag ERF (or PI error-number ELN) from the error flag buffer transferring unit (504, 511) to the buffer memory 5; FIG. 13C shows the read/write access for the ECC block to the buffer memory 5 associated with the decoding process in the PO lost correction processing unit 506 and the EDC decoder 507; FIG. 13D shows the read access for the ECC block from the buffer transferring unit 508 to the buffer memory 5; and FIG. 13E shows the total access to the buffer memory 5 in the entire error correction process.

As shown in FIGS. 13B and 13E, during when the ECC block is written into the buffer memory 5 from the buffer transferring unit 501 or during when each column of the ECC block is read from the buffer memory 5 at the time of the PO lost correction process of the PO lost correction processing unit 506 described later, the error flag buffer transferring unit (504, 511) performs the buffer transfer of the buffered error flags ERF to the buffer memory 5. As a result, the accesses to the buffer memory 5 are performed efficiently among the processing units (501, (504, 511), 506, 507, 508) without a collision.

Bitmap Type

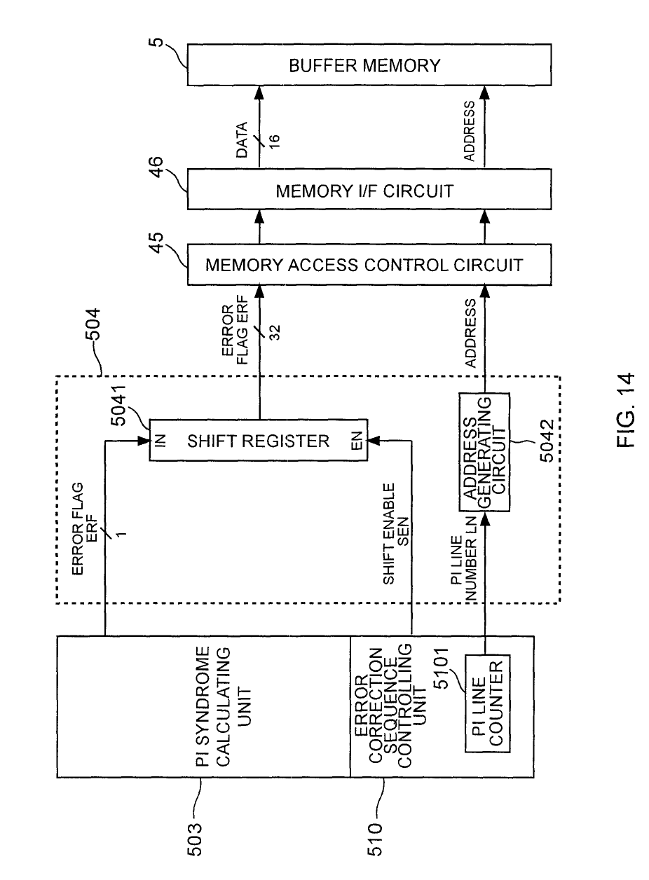

Description will be made of the configuration and operation of the bitmap-type error flag buffering unit 504 with reference to FIG. 14.

A shift register 5041 receives the error flags ERF of all the rows of the ECC block (208 bits) from the PI syndrome calculating unit 503.

An address generation circuit 5402 generates the address information of the error flags ERF that will be stored in the buffer memory 5 based on the PI row numbers LN counted and generated by a PI row counter 5101 and transfers the address information to the memory access control circuit 45. As a result, the buffer transfer is performed for the error flags ERF output from the shift register 5041 based on the address information generated by the address generation circuit 5402 via the memory access control circuit 45 and the memory I/F circuit 46.

By the way, the error flag buffering unit 505 can also be the bitmap type. The configuration in this case is the same as the configuration of the error flag buffering 474 according to the first implementation of the present invention shown in FIG. 5 and will not be described.

Pointer Type

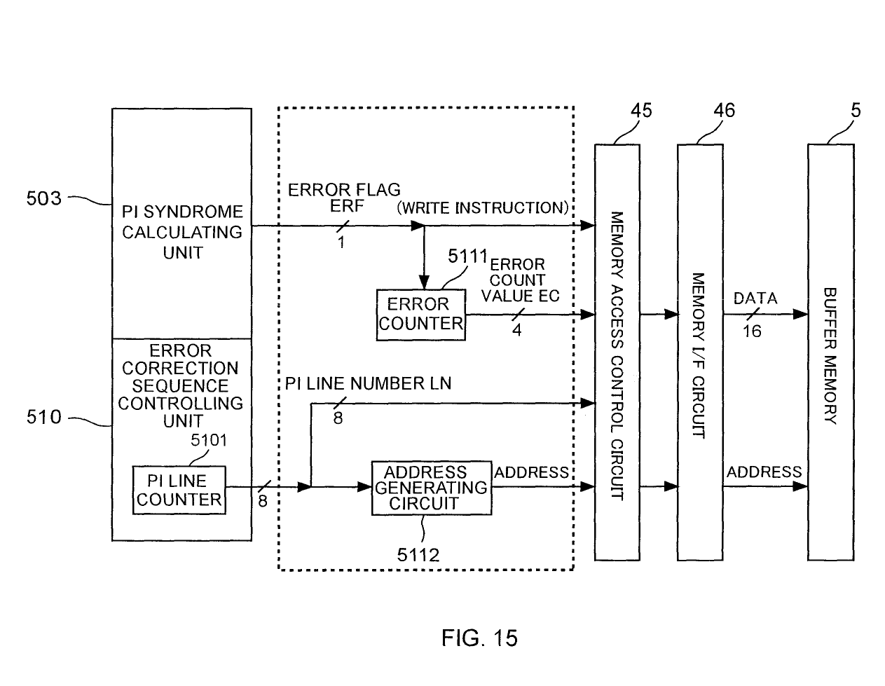

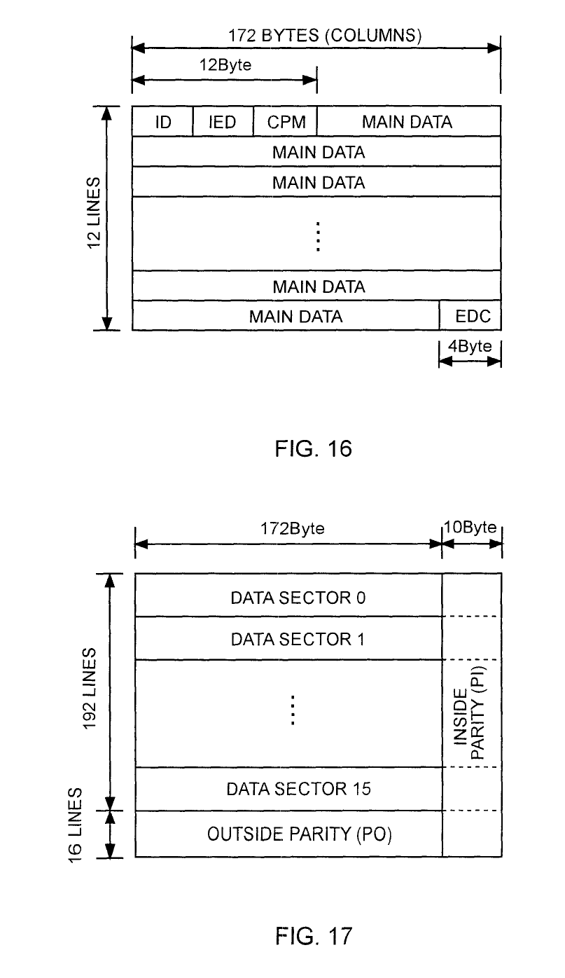

Description will be made of the configuration and operation of the pointer-type error flag buffering unit 511 with reference to FIG. 15.

The error flag buffering unit 511 receives the error flags ERF of each row of the ECC block from the PI syndrome calculating unit 503 and receives the PI row number LN that is the pointer indicating a row of the ECC block corresponding to each error flag ERF from the PI row counter 5101 of an error correction sequence controlling unit 510. The received error flags ERF and PI row numbers LN are transferred to the memory access control circuit 45.

An error counter 5111 counts the number of times of the presence of the error (hereinafter, error count value EC) in the error flags ERF received from the PI syndrome calculating unit 503 and transfers the value to the memory access control circuit 45.

The address generation circuit 5402 generates the address information of the PI error-row number ELN that will be stored in the buffer memory 5 based on the PI row numbers LN received from the PI row counter 5101 and transfers the address information to the memory access control circuit 45.

In this way, the memory access control circuit 45 receives the error flags ERF, the PI row numbers LN, the error count value EC, and the address information from the error flag buffering unit 511. When the received error flag ERF indicates the presence of the error, the memory access control circuit 45 transfers to the memory I/F circuit 46 the PI row number LN (PI error-row number ELN (“error-row pointer”))received in synchronization with the error flag ERF as well as the address information. As a result, the PI error-row number ELN transferred from the memory access control circuit 45 is written into the buffer memory 5 via the memory I/F 46 based on the address information generated by the address generation circuit 5402.

After all the PI error-row numbers ELN corresponding to the error flags ERF of one block are written into the buffer memory 5, the memory access control circuit 45 writes the error count value EC counted by the error counter 511 into the buffer memory 5 as described above. The error count value EC written into the buffer memory 5 can be used for controlling the error flag buffering unit 505 as is the case with the error count value EC of the error counter 4731 of the first implementation described above.

By the way, the error flag buffering unit 505 can also be the pointer type. The configuration in this case is the same as the configuration of the error flag buffering 480 according to the first implementation of the present invention shown in FIG. 8 and will not be described.

Although the implementations of the present invention have been described herein, the above implementations are for the purpose of facilitating the understanding of the present invention and are not for the purpose of limiting the interpretation of the present invention. The present invention may be changed or altered without departing from the sprit thereof and the present invention encompasses equivalents thereof.

What is claimed is:

1. An error correcting apparatus receiving a block code constituted by first error correcting codes in the row direction and second error correcting codes in the column direction to two-dimensionally arranged data to perform an error correction process, the error correcting apparatus comprising:
a buffer memory that stores the block code;
a syndrome calculating unit that performs syndrome calculations based on the first error correcting code in each row of the block code to generate a determination result indicating presence or absence of one or more errors in each row of the block code;
a buffering unit that buffers the determination result; and
a correction processing unit that performs a correction process based on the second error correcting code in each column of the block code read from the buffer memory and the determination result buffered in the buffering unit.

2. The error correcting apparatus of claim 1,
wherein the determination result is an error flag that express the presence or absence of one or more errors in each row of the block code using a flag, and
wherein the buffering unit includes:
a plurality of bitmap registers that buffer the error flags of all the rows of the block code; and
a switching controlling unit that performs control for switching whether one of the plurality of bitmap registers is connected to the correction processing unit.

3. The error correcting apparatus of claim 1,
wherein the determination result is an error-row pointer that indicates a row including one or more errors among the rows of the block code,, and
wherein the buffering unit includes:
a plurality of error-row pointer storing memories that can be accessed by the syndrome calculating unit and the correction processing unit, the error-row pointer storing memories buffering the error-row pointers; and
a switching controlling unit that performs control for switching whether one of the plurality of error-row pointer storing memories is connected to the correction processing unit.

4. The error correcting apparatus of claim 3,
wherein the buffering unit includes an error counter that counts the number of the error-row pointers buffered in the error-row pointer storing memories.

5. An error correcting apparatus receiving a block code constituted by first error correcting codes in the row direction and a second error correcting code in the column direction to two-dimensionally arranged data to perform an error correction process, the error correcting apparatus comprising:
a buffer memory that stores the block code;
a syndrome calculating unit that performs syndrome calculations based on the first error correcting code in each row of the block code to generate a determination result indicating presence or absence of one or more errors in each row of the block code;
a buffer transferring unit that buffers and transfers the determination result to the buffer memory;
a buffering unit that buffers the determination result read from the buffer memory; and
a correction processing unit that performs a correction process based on the second error correcting code in each column of the block code read from the buffer memory and the determination result buffered in the buffering unit.

6. The error correcting apparatus of claim 5,
wherein the determination result is an error flag that expresses the presence or absence of one or more errors in each row of the block code using a flag, and
wherein the buffer transferring unit includes:
a plurality of bitmap registers that store the error flags of the block code; and
an address generation circuit that generates an address for writing the error flag into the buffer memory.

7. The error correcting apparatus of claim 5,
wherein the determination result is an error-row pointer that indicates a row including an error among the rows of the block code, and
wherein the buffer transferring unit includes:
an address generation circuit that generates an address for writing the error-row pointer into the buffer memory.

8. The error correcting apparatus of claim 7,
wherein the buffer transferring unit includes an error counter that counts the number of the error-row pointers.
